(19) United States
(12) Patent Application Publication
(10) Pub. No.: US 2023/0025676 A1
(43) Pub. Date: Jan. 26, 2023

(54) HEAT DISSIPATION SUBSTRATE STRUCTURE HAVING NON-RECTANGULAR HEAT DISSIPATION LAYER

(71) Applicant: AMULAIRE THERMAL TECHNOLOGY, INC., New Taipei City (TW)

(72) Inventors: CHING-MING YANG, New Taipei City (TW); TZE-YANG YEH, New Taipei City (TW)

(21) Appl. No.: 17/382,358

(22) Filed: Jul. 22, 2021

(51) Int. Cl. H01L 23/367

(52) U.S. Cl. CPC H01L 23/367; H01L 23/3735

(57) ABSTRACT

A heat dissipation substrate structure having a non-rectangular heat dissipation layer is provided. The heat dissipation substrate structure having the non-rectangular heat dissipation layer includes a heat dissipation substrate and the non-rectangular heat dissipation layer. The non-rectangular heat dissipation layer is disposed on the heat dissipation substrate, and has one or more positioning features located at one corner of a brazing area of the non-rectangular heat dissipation layer, so as to position a component for subsequent brazing. The non-rectangular heat dissipation layer has one or a plurality of heat dissipation pins that extend from one or more sides of the brazing area of the non-rectangular heat dissipation layer.

### FIELD OF THE DISCLOSURE

The present disclosure relates to a heat dissipation substrate structure, and more particularly to a heat dissipation substrate structure having a non-rectangular heat dissipation layer.

### BACKGROUND OF THE DISCLOSURE

Power chips in a power module of current electric/hybrid vehicles operate on high power. Without appropriate heat dissipation measures, a temperature of the power chip may exceed an allowable temperature, thereby resulting in performance deterioration and damage of the power chip.

Reference is made to FIG. 1 and FIG. 2, in which a conventional power chip 900 is generally provided on a DBC (direct bonding copper: ceramic-metal composite board structure) board 800. Components of the DBC board 800 are arranged, from top to bottom, in the following order: an upper copper layer 801, a ceramic layer 802, and a lower copper layer 803. The DBC board 800 is a copper sheet 20A that is brazed to a surface of a heat dissipation substrate 10A of a heat dissipation substrate structure 700A. In addition, a size of a surface heat dissipation region 201A (or a brazing area) of the copper sheet 20A disposed on the surface of the heat dissipation substrate structure 700A is the same as a size of the brazing area of a bottom portion of the DBC board 800 that is to be brazed, so as to provide good positioning during a brazing process. Therefore, an area of the surface heat dissipation region cannot be increased, and thus heat dissipation performance cannot be enhanced.

### SUMMARY OF THE DISCLOSURE

In response to the above-referenced technical inadequacies, the present disclosure provides a heat dissipation substrate structure having a non-rectangular heat dissipation layer.

In one aspect, the present disclosure provides a heat dissipation substrate structure having a non-rectangular heat dissipation layer, which includes a heat dissipation substrate and one or more non-rectangular heat dissipation layers. The one or more non-rectangular heat dissipation layers is disposed on the heat dissipation substrate, and has one or more positioning features located at one or more corners of a brazing area of the one or more non-rectangular heat dissipation layers, so as to position a component for subsequent brazing. The one or more non-rectangular heat dissipation layers has one or a plurality of heat dissipation pins that extend from one or more sides of the brazing area of the one or more non-rectangular heat dissipation layers.

In certain embodiments, the one or more non-rectangular heat dissipation layers is one of a metal heat dissipation layer and a non-metal heat dissipation layer.

In certain embodiments, the one or more non-rectangular heat dissipation layers is a cold sprayed layer formed on the heat dissipation substrate by cold spraying, and a cold spray material used to form the cold sprayed layer is selected from one of copper, silver and nickel.

In certain embodiments, the one or more non-rectangular heat dissipation layers has four of the positioning features respectively located at four of the corners of the brazing area of the one or more non-rectangular heat dissipation layers, and the positioning features are right angle structures.

In certain embodiments, the one or more non-rectangular heat dissipation layers has four of the positioning features respectively located at four of the corners of the brazing area of the one or more non-rectangular heat dissipation layers, and the positioning features are rounded corner structures.

In certain embodiments, the one or more non-rectangular heat dissipation layer has four of the positioning features respectively located at four of the corners of the brazing area of the one or more non-rectangular heat dissipation layers, and the positioning features are sharp corner structures.

In certain embodiments, the one or more non-rectangular heat dissipation layers has four of the positioning features respectively located at four of the corners of the brazing area of the one or more non-rectangular heat dissipation layers, and the positioning features are any combination of right angle structures, rounded corner structures, and sharp corner structures.

In certain embodiments, the one or more non-rectangular heat dissipation layers has four of the heat dissipation pins that respectively extend from four of the sides of the brazing area of the one or more non-rectangular heat dissipation layers, and a hollow structure is formed between at least two of the heat dissipation pins that are adjacent and connected to each other.

In certain embodiments, at least two of the heat dissipation pins of at least two of the non-rectangular heat dissipation layers are connected to each other.

In certain embodiments, the at least two of the heat dissipation pins of the at least two of the non-rectangular heat dissipation layers are connected to each other by a connecting bridge therebetween.

In certain embodiments, the connecting bridge extends outward to form a connecting heat dissipation pin.

In certain embodiments, at least two of the heat dissipation pins of at least two of the non-rectangular heat dissipation layers are connected to each other by a connecting bridge between the at least two of the heat dissipation pins, and the connecting bridge extends outward to form a connecting heat dissipation pin that is connected to one of the non-rectangular heat dissipation layers, so as to form a hollow structure.

Therefore, one of the beneficial effects of the present disclosure is that, in the heat dissipation substrate structure having the non-rectangular heat dissipation layer provided by the present disclosure, by virtue of “the non-rectangular heat dissipation layer having positioning features located at one corner of the brazing area of the non-rectangular heat dissipation layer, and the non-rectangular heat dissipation layer having one or a plurality of heat dissipation pins extending from one or more sides of the brazing area of the non-rectangular heat dissipation layer”, easy positioning can be achieved and an area of a surface heat dissipation region can be increased, thereby significantly enhancing heat dissipation performance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a conventional heat dissipation substrate structure being configured to include a DBC board and a power chip;

FIG. 2 is a schematic top view of the conventional heat dissipation substrate structure;

FIG. 3 is a schematic top view of a heat dissipation substrate structure according to one embodiment of the present disclosure;

FIG. 4 is a schematic side view of the heat dissipation substrate structure being configured to include the DBC board and the power chip according to one embodiment of the present disclosure;

FIG. 5 is a schematic top view of the heat dissipation substrate structure according to one embodiment of the present disclosure;

FIG. 6 is a schematic top view of the heat dissipation substrate structure according to one embodiment of the present disclosure;

FIG. 7 is a schematic top view of the heat dissipation substrate structure according to one embodiment of the present disclosure;

FIG. 8 is a schematic top view of the heat dissipation substrate structure according to one embodiment of the present disclosure; and

FIG. 9 is a schematic top view of the heat dissipation substrate structure according to one embodiment of the present disclosure.

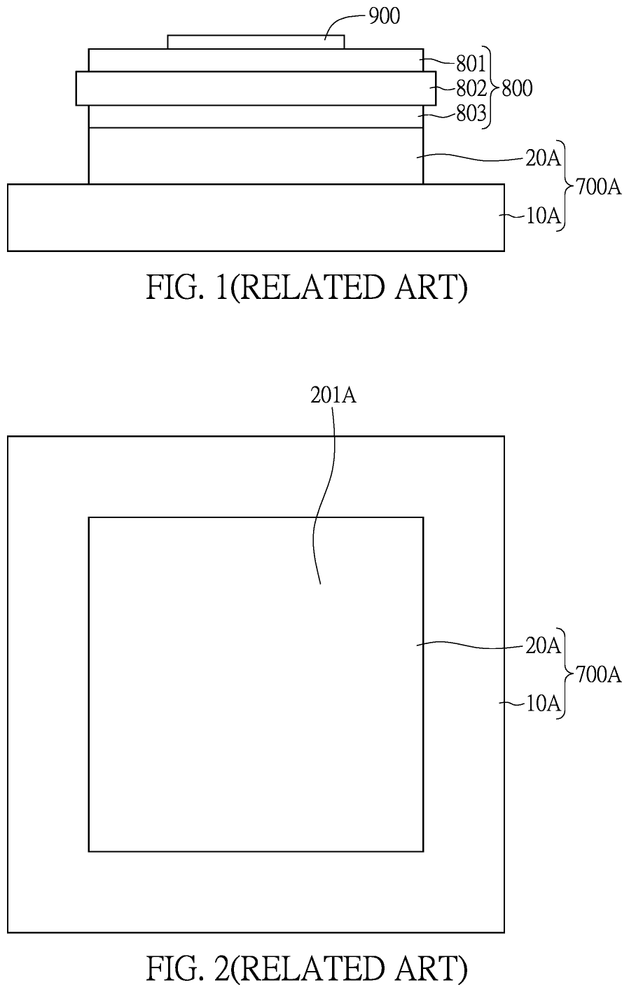

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

Referring to FIG. 2 and FIG. 3, the present disclosure provides a heat dissipation substrate structure having a non-rectangular heat dissipation layer. As shown in the figures, a heat dissipation substrate structure 700 having a non-rectangular heat dissipation layer provided by the present disclosure basically includes a heat dissipation substrate 10 and a non-rectangular heat dissipation layer 20.

In continuation of the above, the non-rectangular heat dissipation layer 20 is disposed on the heat dissipation substrate 10. The heat dissipation structure 10 can be an aluminum heat sink or a metal substrate having heat dissipation function, but is not limited thereto.

Moreover, the non-rectangular heat dissipation layer 20 can be a metal heat dissipation layer or a non-metal heat dissipation layer. In the present embodiment, the non-rectangular heat dissipation layer 20 is a cold spray layer formed on the heat dissipation substrate 10 by cold spraying, and a cold spray material used to form the cold spray layer can be selected from one of copper, silver, and nickel.

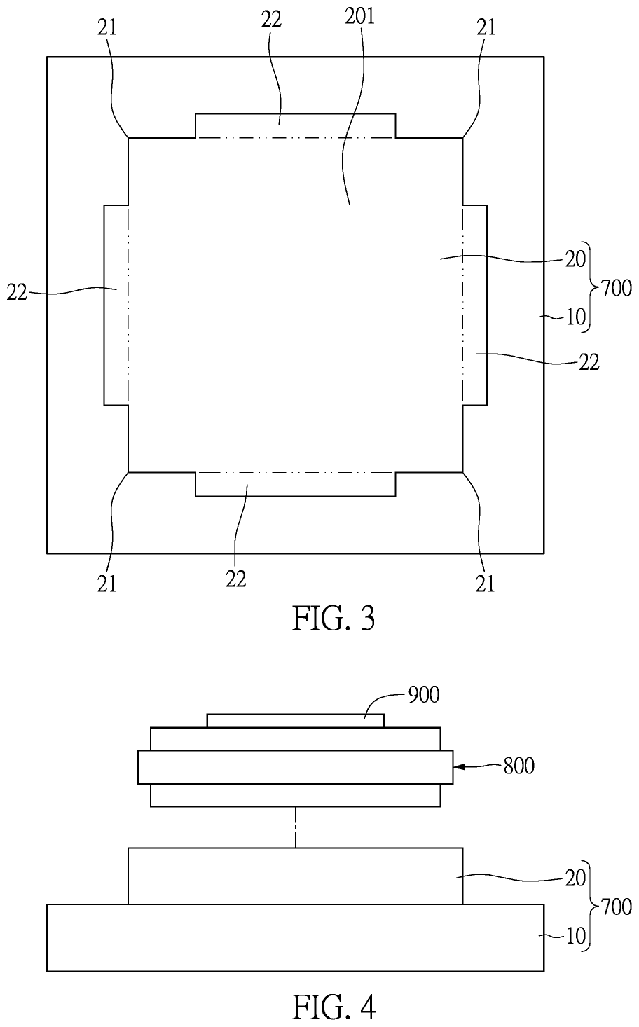

In the present embodiment, the non-rectangular heat dissipation layer 20 has a plurality of positioning features 21 located at a plurality of corners of a brazing area 201 of the non-rectangular heat dissipation layer, which are used to position components for subsequent brazing. The components for subsequent brazing can be, for example, the DBC board 800 as shown in FIG. 4, but is not limited thereto. Furthermore, the non-rectangular heat dissipation layer 20 of the present embodiment has four of the positioning features 21 respectively located at four of the corners of the brazing area 201 of the non-rectangular heat dissipation layer 20, and a rectangular area enclosed by the four positioning features 21 is defined as the brazing area 201. The four of the positioning features 21 are all right angle structures, and the four of the corners of the brazing area of a bottom portion of the DBC board are also right angle structures. A size of the brazing area is the same as a structure of the corners, so as to facilitate positioning. In addition, the non-rectangular heat dissipation layer 20 has one or a plurality of heat dissipation pins 22 that extend from one or more sides of the brazing area 201 of the non-rectangular heat dissipation layer 20. In the present embodiment, the non-rectangular heat dissipation layer 20 has four of the heat dissipation pins 22 that extend from four sides of the brazing area 201 of the non-rectangular heat dissipation layer 20. Therefore, the four of the heat dissipation pins 22 respectively extend from the four sides of the brazing area 201 of the non-rectangular heat dissipation layer 20, so as to increase an area of a surface heat dissipation region and to significantly enhance heat dissipation performance.

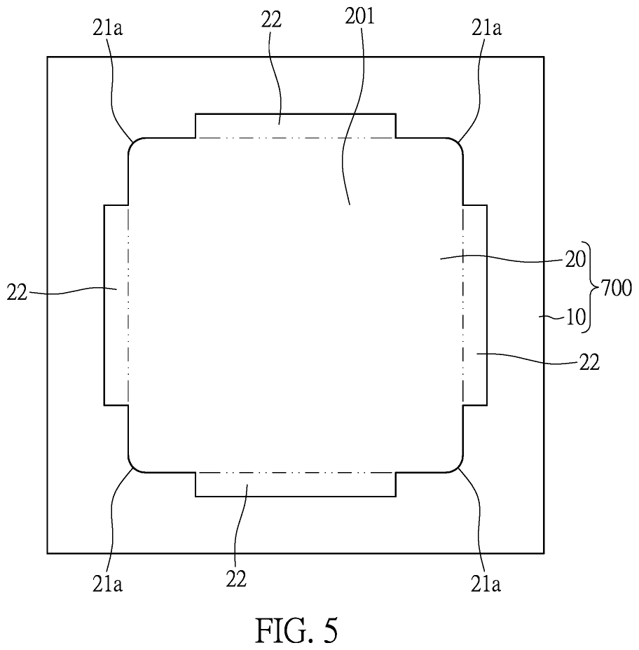

As shown in FIG. 5, the non-rectangular heat dissipation layer 20 of one embodiment has four of the positioning features 21a respectively located at four of the corners of the brazing area 201 of the non-rectangular heat dissipation layer 20. The four of the positioning features 21a are all rounded structures, and the four of the corners of the brazing area of the components for subsequent brazing can also be the rounded structures, so as to facilitate positioning.

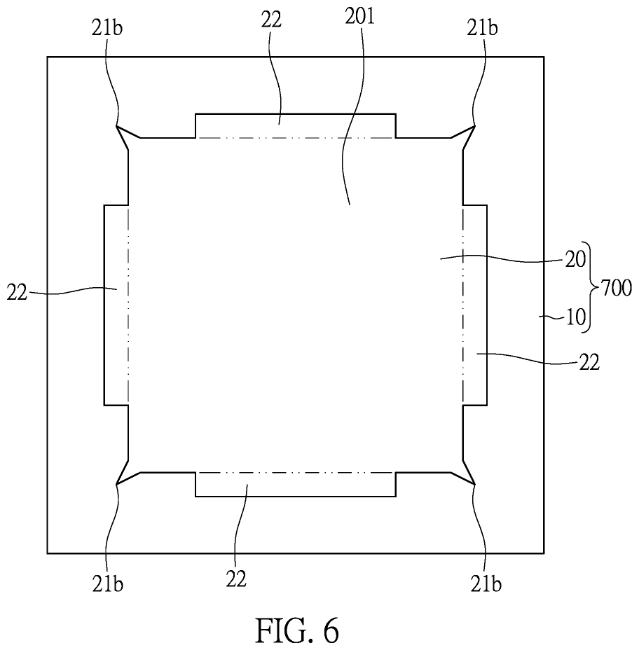

As shown in FIG. 6, the non-rectangular heat dissipation layer 20 of one embodiment has four of the positioning features 21b respectively located at four of the corners of the brazing area 201 of the non-rectangular heat dissipation layer 20. The four of the positioning features 21b are all sharp corner structures, and the four of the corners of the brazing area of the components for subsequent brazing can also be the sharp corner structures, so as to facilitate positioning.

Therefore, it is worth mentioning that the positioning features respectively located at the corners of the brazing area 201 of the non-rectangular heat dissipation layer 20 can be the right angle structures, the rounded structures, the sharp corner structures, or any combination of composite features, and the corners of the brazing area of the components for subsequent brazing can also have similar features, so as to facilitate positioning. In addition, the brazing area can be provided with solder, and a size of the solder can be larger or smaller than the brazing area.

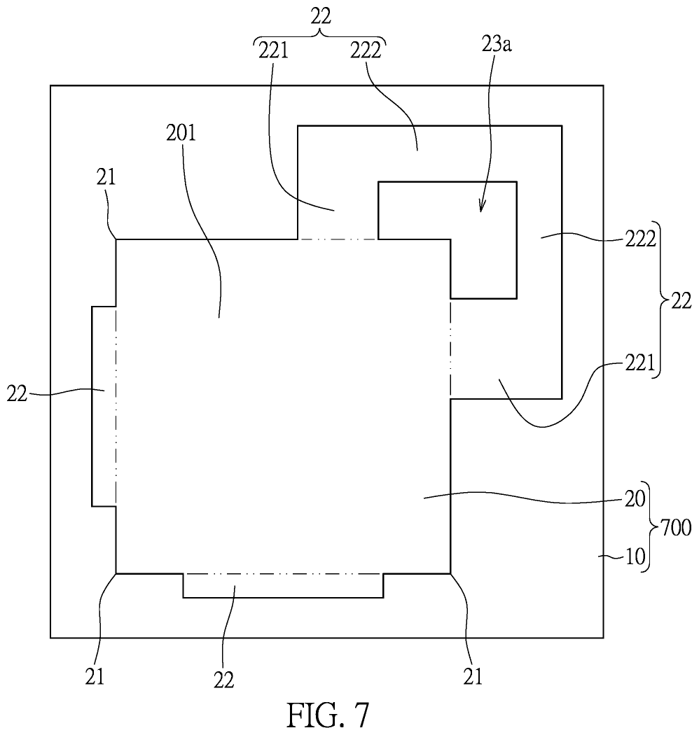

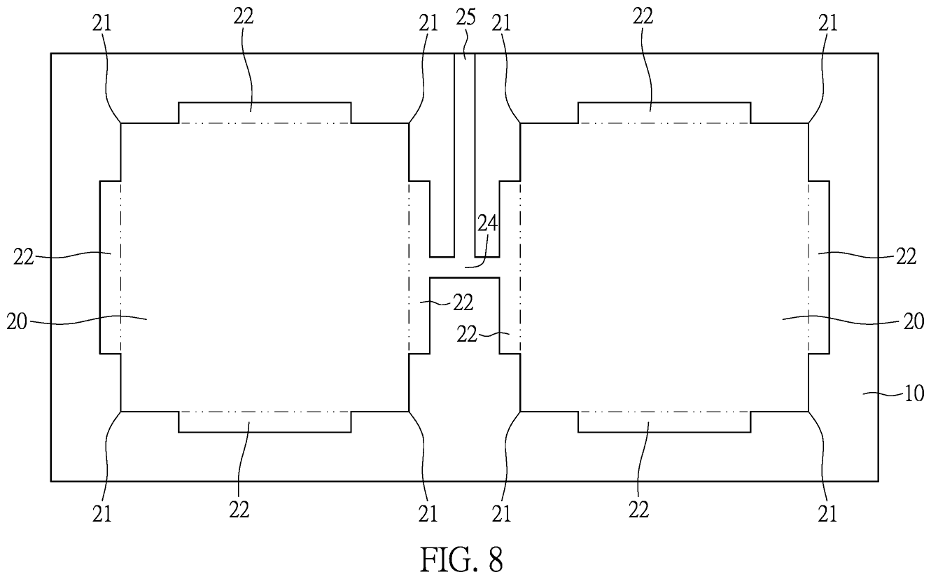

In addition, in order to significantly enhance the heat dissipation performance, the non-rectangular heat dissipation layer 20 of one embodiment has four of the heat dissipation pins 22 that extend from four sides of the brazing area 201 of the non-rectangular heat dissipation layer 20, and a hollow structure 23 is formed between two of the heat dissipation pins 22 that are adjacent and connected to each other (as shown in FIG. 7). Furthermore, the two of the heat dissipation pins 22 that are adjacent to each other respectively extend from two sides of the brazing area 201 to form two extending portions 221, and the two extending portions 221 respectively bend and extend to form two bending portions 222 that are connected to each other and surround the positioning feature to form the hollow structure 23. Moreover, another two of the heat dissipation pins 22 that are adjacent to each other can be disconnected or connected to each other to form another hollow structure.

Therefore, the non-rectangular heat dissipation layer 20 of the present embodiment has a plurality of heat dissipation pins 22 that extend from the sides of the brazing area 201 of the non-rectangular heat dissipation layer 20, and at least two of the heat dissipation pins 22 that are adjacent to each other can be connected to each other to form the hollow structure 23, thereby significantly enhancing the heat dissipation performance.

In one embodiment, as shown in FIG. 8, there are two non-rectangular heat dissipation layers 20, and two of the heat dissipation pins 22 of the two non-rectangular heat dissipation layers 20 are connected to each other. Furthermore, the two of the heat dissipating pins 22 that are adjacent to each other can be directly connected or indirectly connected to each other. In the present embodiment, the two of the heat dissipating pins 22 are connected to each other by a connecting bridge 24 that is horizontally disposed therebetween. Moreover, the connecting bridge 24 further extends outward to form a connecting heat dissipating pin 25 that is vertically disposed, thereby enhancing the heat dissipation performance.

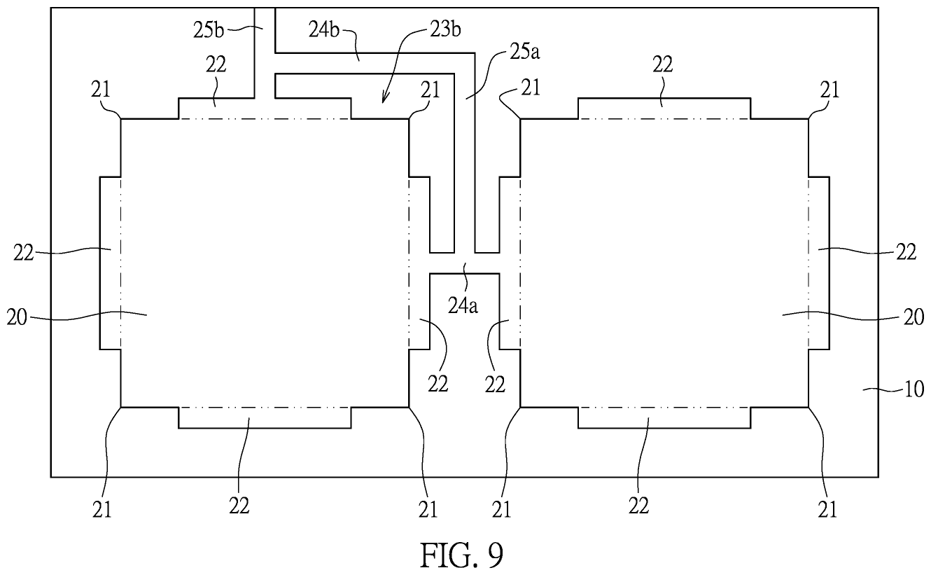

In one embodiment, as shown in FIG. 9, the two of the heat dissipation pins 22 of the two non-rectangular heat dissipation layers 20 are connected to each other by a connecting bridge 24a, and the connecting bridge 24a further extends outward to form a connecting heat dissipation pin 25a that is connected to one of the non-rectangular heat dissipation layers 20, so as to form a hollow structure 23b. In detail, one of the heat dissipation pins 22 of the non-rectangular heat dissipation layers 20 extends outward to form another connecting heat dissipation pin 25b, and the two of the connecting heat dissipation pins 25a, 25b are connected to each other by another connecting bridge 24b that is horizontally disposed therebetween and surround the positioning feature to form the hollow structure 23b, thereby significantly enhancing the heat dissipation performance.

In addition, the present disclosure further provides a manufacturing process of a heat dissipation substrate structure having a non-rectangular heat dissipation layer, which mainly includes the following steps: (a) providing a shielding jig; and (b) using the shielding jig in cooperation with cold spraying. In this way, the non-rectangular heat dissipation layer having heat dissipation pins and positioning features is formed on the heat dissipation substrate, and the non-rectangular heat dissipation layer is used as a component for subsequent brazing (e.g., a DBC board). The heat dissipation substrate can be an aluminum alloy heat sink or a pure aluminum heat sink, and the cold spray material used to form the non-rectangular heat dissipation layer can be selected from one of copper, silver, and nickel.

In conclusion, in the heat dissipation substrate structure 700 having the non-rectangular heat dissipation layer provided by the present disclosure, by virtue of “the non-rectangular heat dissipation layer 20 having positioning features 21 located at one corner of the brazing area 201 of the non-rectangular heat dissipation layer 20, and the non-rectangular heat dissipation layer 20 having one or a plurality of heat dissipation pins 22 extending from one or more sides of the brazing area 201 of the non-rectangular heat dissipation layer 20”, easy positioning can be achieved and the area of the surface heat dissipation region can be increased, thereby significantly enhancing the heat dissipation performance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

1. A heat dissipation substrate structure, comprising:
a heat dissipation substrate and one or more non-rectangular heat dissipation layers, wherein the one or more non-rectangular heat dissipation layers is disposed on the heat dissipation substrate, and has one or more positioning features located at one or more corners of a brazing area of the one or more non-rectangular heat dissipation layers, the brazing area is located at a top surface of the one or more non-rectangular heat dissipation layers, and corresponds in size to a bottom surface of a component that is brazed on the top surface of the one or more non-rectangular heat dissipation layers; wherein the one or more non-rectangular heat dissipation layers has one or a plurality of heat dissipation pins that extend from one or more sides of the brazing area of the one or more non-rectangular heat dissipation layers, and the one or more non-rectangular heat dissipation layers is cold sprayed onto the heat dissipation substrate such that a bottom surface of the one or more non-rectangular heat dissipation layers is fully in contact with the heat dissipation substrate, so as to enhance bonding strength and heat dissipation performance.

2-3. (canceled)

4. The heat dissipation substrate structure according to claim 1, wherein the one or more non-rectangular heat dissipation layers has four of the positioning features respectively located at four of the corners of the brazing area of the one or more non-rectangular heat dissipation layers, and the positioning features are right angle structures.

5. The heat dissipation substrate structure according to claim 1, wherein the one or more non-rectangular heat dissipation layers has four of the positioning features respectively located at four of the corners of the brazing area of the one or more non-rectangular heat dissipation layers, and the positioning features are rounded corner structures.

6. The heat dissipation substrate structure according to claim 1, wherein the one or more non-rectangular heat dissipation layers has four of the positioning features respectively located at four of the corners of the brazing area of the one or more non-rectangular heat dissipation layers, and the positioning features are sharp corner structures.

7. The heat dissipation substrate structure according to claim 1, wherein the one or more non-rectangular heat dissipation layers has four of the positioning features respectively located at four of the corners of the brazing area of the one or more non-rectangular heat dissipation layers, and the positioning features are any combination of right angle structures, rounded corner structures, and sharp corner structures

8. The heat dissipation substrate structure according to claim 1, wherein the one or more non-rectangular heat dissipation layers has four of the heat dissipation pins that respectively extend from four of the sides of the brazing area of the one or more non-rectangular heat dissipation layers, and a hollow structure is formed between at least two of the heat dissipation pins that are adjacent and connected to each other.

9. The heat dissipation substrate structure according to claim 1, wherein at least two of the heat dissipation pins of at least two of the non-rectangular heat dissipation layers are connected to each other.

10. The heat dissipation substrate structure according to claim 9, wherein the at least two of the heat dissipation pins of the at least two of the non-rectangular heat dissipation layers are connected to each other by a connecting bridge between the at least two of the heat dissipation pins.

11. The heat dissipation substrate structure according to claim 10, wherein the connecting bridge extends outward to form a connecting heat dissipation pin.

12. The heat dissipation substrate structure according to claim 1, wherein at least two of the heat dissipation pins of at least two of the non-rectangular heat dissipation layers are connected to each other by a connecting bridge between the at least two of the heat dissipation pins, and the connecting bridge extends outward to form a connecting heat dissipation pin that is connected to one of the non-rectangular heat dissipation layers, so as to form a hollow structure.
